(19) United States
(12) Patent Application Publication
(10) Pub. No.: US 2012/0061815 A1
(43) Pub. Date: Mar. 15, 2012

(54) POWER SEMICONDUCTOR MODULE HAVING SINTERED METAL CONNECTIONS, PREFERABLY SINTERED SILVER CONNECTIONS, AND PRODUCTION METHOD

(75) Inventors: Peter Sontheimer, Baierbrunn (DE); Attila Ori, Bicske (HU)

(73) Assignee: VINCOTECH HOLDINGS S.A.R.L., Luxembourg (LU)

(21) Appl. No.: 13/226,998

(22) Filed: Sep. 7, 2011

(30) Foreign Application Priority Data
Sep. 8, 2010 (DE) 10 2010 044 709.9

(51) Int. Cl. H01L 23/495; H01L 21/50

(52) U.S. Cl. 257/676; 438/123; 257/E23.052; 257/E21.499

(57) ABSTRACT

A power semiconductor module having a substrate (102), at least one power semiconductor device (104) and at least one lead frame element (106), and a method for producing such a power semiconductor module (100). The connection between the at least one first lead frame element and the power semiconductor device as well as the connection between the first lead frame element and the substrate comprise a sintered metal connection (110), preferably a sintered silver connection.

### BACKGROUND OF THE INVENTION

The present invention relates to a power semiconductor module having a substrate, at least one power semiconductor device and at least one lead frame element. The present invention further relates to a production method for such a power semiconductor module.

Specifically, the present invention relates to mounting and interconnection techniques for such power semiconductor modules, which will be referred to as “power modules” below. To this end, as is generally known, substantially two important electrical connections have to be closed, namely the connection between the semiconductor device (also referred to as “chip”) and a substrate as well as other internal devices on the one hand, and the electrical connection to the outer environment on the other hand.

In general, modern power modules involve the problem that significant quantities of waste heat induced by the needed high powers have to be dissipated from the semiconductor elements. In addition, it is required to obtain a great robustness and current-carrying capacity for all electrical connections. At the same time, the production costs should be as low as possible.

A first known arrangement for encapsulating a power semiconductor device will be explained in detail below with reference to FIG. 4. In this arrangement, a known power semiconductor module 400 comprises a substrate 402 with a power semiconductor device 404 mounted thereon. Generally, the substrate 402 of this prior solution is a direct copper bonding, DCB, substrate, and the semiconductor device 404 is soldered to the DCB substrate at the contact points 406. In a second working step, pins 408 are soldered to the DCB substrate 402 to obtain contacts to the outside. For the final assembly these pins 408 are connected to corresponding conductor tracks on a printed circuit board, PCB, or, alternatively, are injected or inserted into the housing. To this end, press-in contacts as well as another soldering step are applied. The mechanical connection to the printed circuit board 410 is accomplished by screw connections 412. By means of another screw connection 414 or snap-in clips the arrangement is connected to a heat sink 416. In the Anglo-Saxon language use the term direct bonded copper, DBC, substrate is, incidentally, often used as well.

The advantage of this known arrangement is the very high flexibility with respect to the circuit configuration. Also, the production in small numbers is easy to realize. However, this solution involves the drawback that the production costs per item are relatively high. The reason for this is that a plurality of complex mounting steps have to be carried out as the chips are initially soldered to the ceramic substrate, which simultaneously ensures the electrical insulation from the rest of the system, and, in the second step, the connecting pins 408 are soldered to the DCB substrate 402.

Another known arrangement is illustrated in FIG. 5. As an alternative to the connecting pins 408 of the arrangement shown in FIG. 4 the power module 500 shown in this figure is provided with lead frame fingers 506. Different semiconductor devices 504 are here mounted on the DCB substrate 502 and are soldered to the copper structures 505 of the DCB substrate 502 in a manner known per se. The required connection towards the outside is likewise produced by lead frames 506 which are soldered to corresponding copper structures. As compared with the arrangement of FIG. 4, the process management for producing the arrangement of FIG. 5 is simplified to the effect that the lead frame elements 506 can be mounted simultaneously with the devices 504. However, this known arrangement still requires a separate bonding step for producing an electrical connection between the semiconductor devices 504 and the respective lead frame elements 506. Moreover, this arrangement is only suited for relatively simple topologies. Finally, this known alternative exhibits a relatively great complexity and is less flexible than the arrangement of FIG. 4.

Moreover, as will be explained with reference to FIGS. 6 and 7, it is also known to completely waive an insulating substrate and connect the devices directly to a lead frame instead. Such power modules are known, for instance, from the article H. Kawafuji et al.: “DIP-IPM der 4. Generation-Transfer-Mold-DIP-IPM für 5 bis 35 A/1200 V mit neuartiger Warmefolienisolierung”, http://www.elektronikpraxis.vogel.de/leistungselektronik/articles/150931/, of Nov. 6, 2008. For the heat dissipation a heat sink is provided, which is arranged on the opposite side of the lead frame. A plastic encapsulation of epoxy resin, which is produced by means of a transfer mold, encapsulates the arrangement and electrically insulates the heat sink towards the outside.

In order to improve the heat dissipation of the arrangement of FIG. 6, which is extremely unsatisfactory, it is provided in the arrangement according to FIG. 7 to provide a thin, electrically insulating, yet thermally highly conductive film between the lead frame 706 and the heat sink 716. Thus, it is possible to waive the encapsulation of the metallic heat sink on the outside, which allows the dissipation of more heat to the outside.

The known power semiconductor modules 600, 700 according to FIGS. 6 and 7 have the advantage that the production thereof is extremely cost-efficient for large numbers of items.

However, these prior solutions have the disadvantage that the thermal conditions are still unsatisfactory and that the constructional design with respect to the electrical insulation is relatively complicated. Finally, the production of modules 600, 700 requires relatively expensive tools.

### SUMMARY OF THE INVENTION

Therefore, it is the object of the present invention to improve a power semiconductor module of the aforementioned type to the effect that the production is simplified, the heat dissipation as well as the electrical insulation are optimized and, at the same time, the current-carrying capacity is increased.

This object is achieved with the subject matter of the independent patent claims. Advantageous embodiments of the inventive power semiconductor module and the inventive production method are defined in the dependent patent claims.

In order to permit the utilization of novel chips having an increased specified operating temperature, by making use of their maximally possible use parameter, it is known to replace the conventional chip soldering method by a metal sintering method, specifically by a silver sintering method.

An arrangement known per se, where a chip is bonded to a circuit carrier by means of a silver sintering method, is illustrated in FIGS. 8 and 9. To this end, a power semiconductor device 804, 904 and a carrier 802, 902 are pressed together at an increased temperature and with a high pressure. A silver paste 810, 910, which is applied between the chip 804, 904 and the carrier material 802, 902, is adapted to form under these conditions permanent molecular bonds with both bonding partners, wherein the substrate is, for instance, an aluminum oxide substrate 802, 902 with two copper layers applied to both sides. An additional copper plate 915, which is coupled to the carrier 902 by means of a solder layer 908, can improve the heat transfer to a heat sink 916. A thermally conductive intermediate layer (“thermal grease”) 812, 912 ensures an optimum heat transfer by a corresponding tolerance compensation. According to these known solutions the electrical connection of the power semiconductor modules 800, 900 towards the outside is accomplished, again, by soldered or pressed-in pins 806, 906.

Mechanically, the silver sintering method allows very robust solutions even under difficult temperature operating conditions.

Therefore, the present invention is based on the idea to make use of the metal sintering technology, and specifically of the silver sintering technology, according to an improved process management for the production of a robust and cost-efficient power semiconductor module.

According to the invention at least one first lead frame element is connected to the power semiconductor device on a first surface and is connected to the substrate on a second surface which is opposite the first surface. According to the invention, the connection between the at least one first lead frame element and the power semiconductor device as well as the connection between the first lead frame element and the substrate are produced by a metal sintering method in a single production step.

For instance, a ceramic substrate such as aluminum oxide (Al₂O₃) is suited as substrate, which has good thermal conduction properties. Of course, other suited materials may be applied as well. According to the invention, particularly also very thin substrates, specifically thin-film or thick-film substrates may be used as carrier material for such a power semiconductor module if a metal sintering method is employed.

The carrier material is provided with a previously printed and burnt-in metal layer, preferably a silver coating, and a metal layer capable of being sintered is applied between the chip and the lead frame as well as between the lead frame and the carrier. In this respect it is of no relevance to which of the two contact partners the metal layer to be sintered is applied. Next, the chip and the lead frame are positioned on the carrier material, and, by the action of a suited temperature and the exertion of a mechanical pressure, the bonding partners chip/lead frame and lead frame/carrier form a permanent mechanical bond.

Thus, the method applied is advantageously a “one step assembly” method for the chip and interconnection technique in one simultaneous working step.

As compared with the above-described known arrangements the omission of a separate cost-intensive process step brings about significant cost advantages. Moreover, the electric layout can already be implemented in an advantageous manner by the lead frame structure. The system according to the invention as a whole is extremely reliable and robust, and the electric power to be realized is upwardly scalable without limits.

Hence, the power semiconductor modules according to the present invention can advantageously be used in a plurality of fields of application, such as drive control, renewable energies, uninterrupted power supply, electrical driving, but also for welding and cutting, power supply units, medical engineering apparatus or railway engineering.

In addition, the present invention can be used for complete power modules, but also for individual power semiconductor devices, i.e. discrete semiconductors. In any of these fields of application the mounting and interconnection technique according to the invention provides for the significant advantages in view of cost saving and the extremely high thermomechanical stability and reliability.

According to an advantageous embodiment of the present invention at least one second lead frame element is provided, which is connected to the power semiconductor device on a first surface by means of a wire bond connection and to the substrate on a second surface, which is opposite the first surface, by means of a sintered metal connection. This solution allows the additional production of other connections towards the outside.

Furthermore, the arrangement according to the invention can still be extended to even broader layered (sandwich) constructions. At least one third lead frame element can be arranged on the surface of the power semiconductor device that is opposite the first lead frame element, so that the semiconductor device is arranged between the two lead frames. According to the invention, the electrical connection between the third lead frame element and the power semiconductor device, too, is accomplished by a sintered metal connection produced in the one production step. This arrangement is yet a further simplification step in the production of discrete components, the advantage of which consists in an extraordinary reliability and excellent power-carrying capacity.

Advantageously, the principles according to the invention in combination with a sintered silver connection are made use of in the form of a sintered metal layer. The person skilled in the art will appreciate, however, that the metal particles to be sintered can include not only silver, but also gold, copper, platinum, palladium, rhodium, osmium, ruthenium, iridium, iron, tin, zinc, cobalt, nickel, chromium, titanium, tantalum, tungsten, indium, silicon, aluminum and the like, or an alloy of at least two metals.

### BRIEF DESCRIPTION OF THE DRAWINGS

For a better understanding of the present invention the latter will be explained in more detail below by means of the embodiment examples illustrated in the figures, wherein like parts are provided with like reference numbers and like component designations. Also, some features and feature combinations from the embodiments shown and described may represent independent inventive solutions or solutions according to the invention. In the drawings:

FIG. 1 shows a schematic representation of a power semiconductor module according to a first advantageous embodiment;

FIG. 2 shows a schematic representation of a second embodiment of the power semiconductor module according to the invention;

FIG. 3 shows a schematic representation of a discrete semiconductor with a layered structure;

FIG. 4 shows a schematic representation of a first known power semiconductor module;

FIG. 5 shows a perspective representation of a second known power semiconductor module;

FIG. 6 shows a schematic representation of a third known power semiconductor module;

FIG. 7 shows a schematic representation of a fourth power semiconductor module;

FIG. 8 shows a schematic representation of a sintered silver assembly on a ceramic substrate without a copper base plate;

FIG. 9 shows a schematic representation of a sintered silver assembly of a device on a ceramic carrier with a copper base plate.

### DETAILED DESCRIPTION

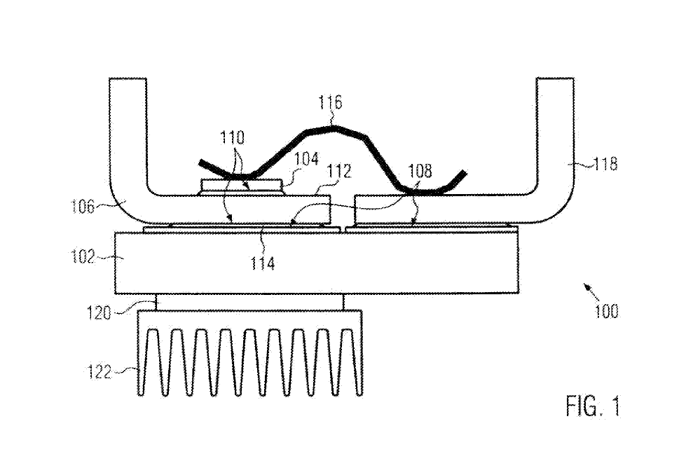

FIG. 1 shows in a schematic representation a first embodiment of a power semiconductor module 100 according to the present invention. The power semiconductor module 100, which will also be referred to as power module below, comprises a substrate 102 which is preferably made of ceramics. Of course, all other common circuit carrier materials may be used as well, e.g. high temperature resistant plastic materials or films.

A structured, printed and burnt-in silver layer 108 is provided on this substrate 102. This silver layer 108 serves the contact making with the inventive sintered silver connection 110. According to the present invention a power semiconductor device, which will also be referred to as chip below, is connected to a first lead frame element 106 on a first surface 112 by means of a sintered silver connection 110. The electrical contact with the substrate 102 is accomplished on the second surface, which is opposite the first surface 112, of the lead frame element 106. According to the inventive solution the connections to the two surfaces 112 and 114 of the lead frame element 106 can be produced in one single pressure sintering step.

According to the inventive method a pasty layer, as is known from sintered connections according to the prior art, is arranged in a step not explicitly described on one (or both) of the partners to be connected, preferably by means of a screen printing technique. The layer thickness of such pasty layers is usually in the range between 10 μm and 20 μm.

The pasty layer itself is made of a mixture of a metallic material in the form of metal flakes, which have a maximum expansion in the magnitude of micrometers, and a solvent. Particularly silver is suited as material for the metal flakes, but also other precious metals or mixtures having a precious metal amount of more than 90%. Thus, the person skilled in the art will appreciate that the present invention cannot only be used for sintered silver connections, but also for other pressure sintering connections. For forming a metallic layer pressure is applied to the pasty layer. Moreover, it is advantageous to expel at least 95% of the solvent from the pasty layer prior to this pressure application. Preferably, this is achieved by means of a temperature rise, e.g. by 350 Kelvin. Also, this temperature rise may be maintained or increased during the subsequent pressure application.

In order to protect the semiconductor device 104 it may further be provided to cover the same during the pressure application, for instance, with a sheet.

In order to achieve a sufficiently adhesive bond between the pasty layer and the contact surface the final maximum pressure of such a pressure application is usually at about 8 MPa.

The contact bond strength between the chip and the lead frame and between the lead frame and the substrate as obtained by the sintered connection is very high. In reliability tests the sintered layers showed a great load alternation strength. Therefore, considerably greater thermal load alternation strengths can be obtained as compared with soldered connections. In the embodiment shown in FIG. 1 the chip 104 is electrically connected to other lead frame elements 118 by means of wire bond connections 116, and these lead frame elements are likewise connected to the substrate 102 by a sintered silver connection 110. Moreover, by means of a thermal grease 120 the side of the substrate 102 facing away from the contact surfaces 108 is connected to a heat sink 122 in order to dissipate the heat. At this point, however, any other common measures for dissipating the excess heat present in the substrate 102 may be used. As is known in power electronics, the thermal grease 120 improves the heat transfer from the substrate 102 to the heat sink 122.

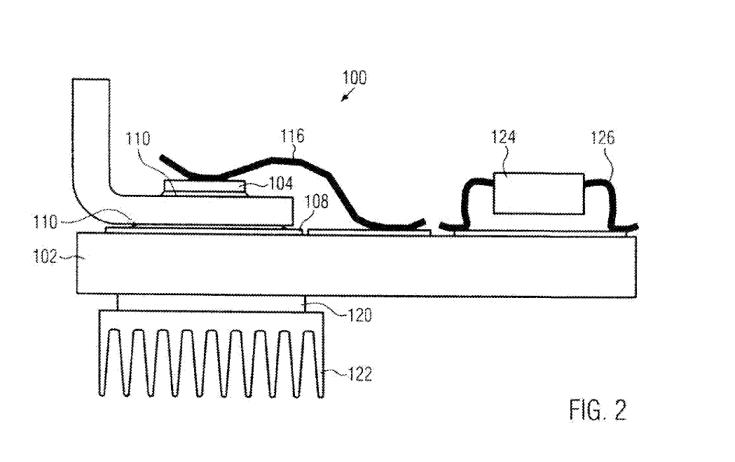

Another advantageous embodiment of the arrangement according to the invention will now be explained with reference to FIG. 2. In this arrangement the wire bond connection from the chip 104 is accomplished not to another lead frame structure 118, but to the printed and structured metallization 108. Moreover, conventional electronic components 124 can be connected to the printed metallization 108 by means of conventional connection techniques, e.g. bonds or soldered connections 126.

The embodiments of FIGS. 1 and 2 have the advantage of a cost-optimized system, wherein the layout is implemented in the lead frame structure. It constitutes a one-step mounting and interconnection technique in which the chip mounting and the connection to a line are accomplished in one working step. The so produced component is extremely reliable and is not limited in terms of power.

The embodiments shown herein have the drawback, however, that an additional wire bond process is necessary. Moreover, the potential of the sintering process, which is relatively complex as such, is not fully exploited.

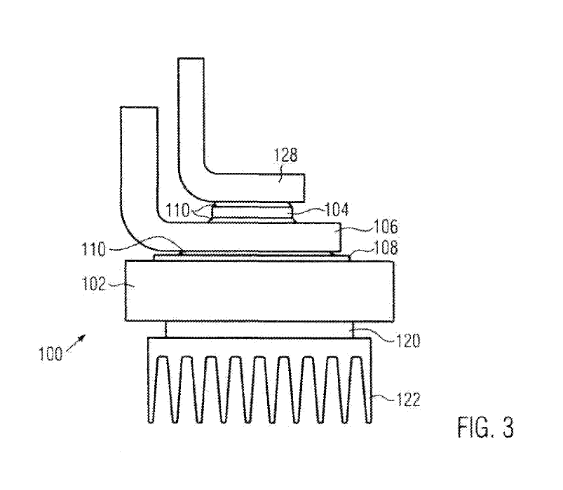

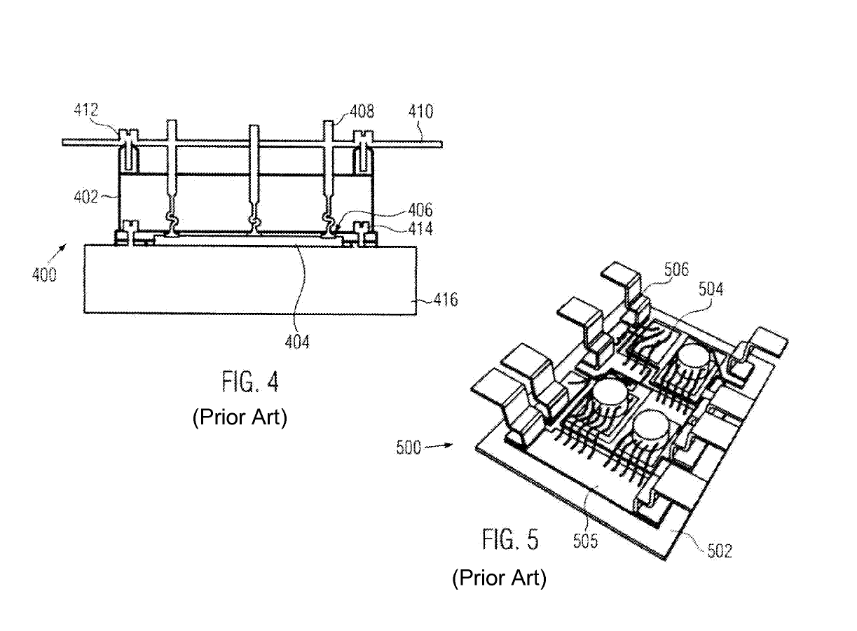

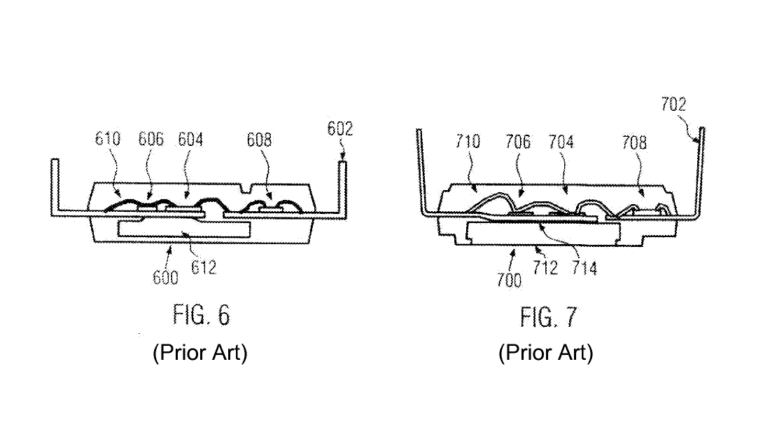

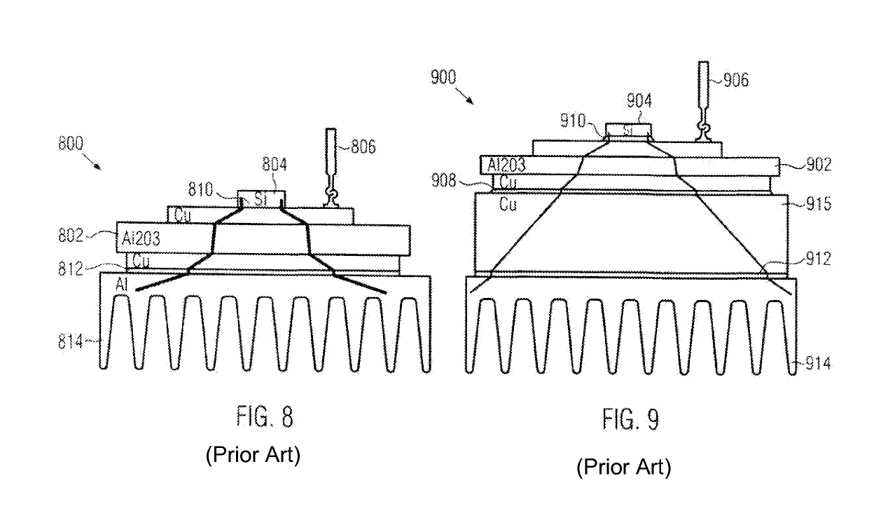

Therefore, according to another embodiment of the present invention, the layered structure outlined in FIG. 3 is proposed. In this arrangement, which is above all suited for the mounting and interconnection technique of discrete components, again a substrate 102 is provided with a structured metallization, preferably a printed and burnt-in silver layer. Next, a lead frame element 106, the power semiconductor device 104 and another lead frame element 128 are stacked on top of each other and connected by interposing a sintered silver precursor in such a way that all sintered silver contacts 110 can be produced simultaneously in one single pressure sintering step. The silver sintering paste is either applied to the lead frame element 128 or to the chip 104 or, if applicable, even to both surfaces to be connected. Particularly advantageously these sandwich constructions can be used for thin-film substrates 102 as both the chip attachment and the electrical connections can thus be achieved in one working step.

Especially for discrete semiconductor components this arrangement constitutes the perfect structure, has the advantage that costs are kept at a minimum along with a greatest possible reliability, and is not subjected to a power limitation in a wide range.

This is of essential significance above all for wind and solar energy, but also for drive technology.

1. A power semiconductor module having a substrate (102), at least one power semiconductor device (104) and at least one first lead frame element (106),
wherein the at least one first lead frame element (106) is connected to the power semiconductor device (104) on a first surface and is connected to the substrate (102) on a second surface which is opposite the first surface,
wherein the connection between the at least one first lead frame element and the power semiconductor device as well as the connection between the first lead frame element and the substrate comprise a sintered metal connection (110).

2. The power semiconductor module according to claim 1, wherein the sintered metal connection (110) comprises a sintered silver connection.

3. The power semiconductor module according to claim 1, wherein the substrate (102) comprises a ceramic substrate.

4. The power semiconductor module according to claim 1, wherein the substrate (102) is a thin-film or a thick-film substrate.

5. The power semiconductor module according to claim 1, wherein printed conductor patterns (108) are arranged on the substrate (102).

6. The power semiconductor module according to claim 1, further comprising at least one second lead frame element (118) which is connected to the power semiconductor device (104) on a first surface by means of a wire bond connection (116) and which is connected to the substrate (102) on a second surface, which is opposite the first surface, by means of a sintered metal connection.

7. The power semiconductor module according to claim 1, further comprising at least one third lead frame element (128) arranged on a surface of the power semiconductor device (104) that is opposite the first lead frame element (106), wherein the electrical connection between the third lead frame element (128) and the power semiconductor device (104) likewise comprises a sintered metal connection.

8. A method for producing a power semiconductor module having a substrate, at least one power semiconductor device and at least one first lead frame element, the method comprising the following steps:
aligning and fixing the power semiconductor device on a first surface of the first lead frame element;
aligning and fixing the first lead frame element on the substrate so that the at least one first lead frame element is connected to the power semiconductor device on a first surface and is connected to the substrate on a second surface which is opposite the first surface,
performing a pressure sintering step so that the connection between the at least one first lead frame element and the power semiconductor device as well as the connection between the first lead frame element and the substrate comprise a simultaneously produced sintered metal connection.

9. The method according to claim 8, wherein the following step is performed prior to performing the sintering step:
applying and structuring a metal paste capable of being sintered to/on the substrate and/or to/on the first and second surface of the first lead frame element and/or to/on the surface of the power semiconductor device facing the first lead frame element.

10. The method according to claim 8, wherein further at least one second lead frame element is connected to the substrate by means of a sintered metal connection and is connected to the power semiconductor device by means of a wire bond connection.

11. The method according to claim 8, wherein further at least one third lead frame element is aligned and fixed on a surface of the power semiconductor device which is opposite the first lead frame element prior to performing the sintering step, and
wherein the electrical connection between the third lead frame element and the power semiconductor device likewise comprises a sintered metal connection.

12. The method according to claim 8, wherein the sintered metal connection comprises a sintered silver connection.
